(19) United States
(12) Patent Application Publication
(10) Pub. No.: US 2024/0283377 A1
(43) Pub. Date: Aug. 22, 2024

(54) LATERALLY MULTILAYERED DIELECTRIC ELASTOMER ACTUATOR AND METHOD OF MANUFACTURING SAME

(71) Applicant: POSTECH RESEARCH AND BUSINESS DEVELOPMENT FOUNDATION, Pohang-si (KR)

(72) Inventors: Kilwon CHO, Pohang-si (KR); Siyoung LEE, Pohang-si (KR); Jonghyun SON, Pohang-si (KR); Geun Yeol BAE, Pohang-si (KR)

(21) Appl. No.: 18/415,874

(22) Filed: Jan. 18, 2024

(30) Foreign Application Priority Data
Feb. 17, 2023 (KR) 10-2023-0021383

(51) Int. Cl. H02N 1/00

(52) U.S. Cl. CPC H02N 1/002

(57) ABSTRACT

Proposed is a laterally multilayered dielectric elastomer actuator and a method of manufacturing the same. The actuator includes a polymer frame, an electrode, and a dielectric elastic portion. The polymer frame includes a first pattern with a first comb shape of a predetermined thickness and a second pattern with a second comb shape of a predetermined thickness. The electrode includes a first electrode formed on a portion of the first pattern and a second electrode formed on a portion of the second pattern. The dielectric elastic portion is interposed between the first electrode and the second electrode and contains a dielectric elastomer. Since the actuators can be laterally stacked, a multilayered actuator in which a large number (several to several thousands) of dielectric elastomer actuators stacked can be manufactured in the form of a very thin film (<50 μm).

### CROSS REFERENCE TO RELATED APPLICATION

The present application claims priority to Korean Patent Application No. 10-2023-0021383, filed Feb. 17, 2023, the entire contents of which is incorporated herein for all purposes by this reference.

### BACKGROUND OF THE DISCLOSURE

### 1. Field of the Disclosure

The present disclosure relates to a laterally multilayered dielectric elastomer actuator and a method of manufacturing the same.

### 2. Description of the Related Art

Wearable haptic feedback devices in the form of clothing are being developed for use in human-machine interfaces and remote surgery. Methods for haptic feedback devices to deliver stimulation to the skin include mechanical, electrical, thermal, and ultrasonic stimulation. Among the stimulation types, mechanical stimulation can provide natural skin stimulation based on the principle that mechanical receptors in human skin accept pressure/vibration. However, existing electromagnetic actuators used for mechanical stimulation have limitations in their use as wearable devices because actuators are relatively bulky and heavy, and have hard materials in use.

Polymer-based soft actuators have the potential to be used in wearable haptic feedback devices because they can have a lighter and thinner structure than existing electromagnetic actuators. As a result, various methods of operating the polymer-based soft actuators using heat, magnetic fields, air pressure, piezoelectricity, and ion movement have been developed. In particular, dielectric elastomer actuators, which operate by deforming dielectric elastomers with electrostatic force, can have vibration stimulation of various frequencies and large magnitudes and have various structures in terms of size and shape based on soft dielectric layers. Therefore, dielectric elastomer actuators are under research and development not only as wearable haptic feedback devices but also as soft robots that replace existing hard robots.

However, the following issues need to be addressed before the dielectric elastomer actuators developed to date can be commercialized.

First, it is necessary to lower the operating voltage of the dielectric elastomer actuators developed so far, which is usually as small as 1 kV and as large as 10 kV or more. This is due to electrostatic forces that work significantly only at very short dielectric distances, which not only require a large voltage amplification device but also pose a risk of leakage current when used. Recently, research has been conducted to lower the operating voltage to less than 1 kV using the same dielectric elastomer structure through a lamination and rolling method, but dielectric elastomer actuators still have an operating voltage of over 500 V.

Second, to manufacture the dielectric elastomer actuators with a laminated structure designed to reduce the operating voltage, there is a problem that the process of forming dielectric layers and corresponding electrodes is required to be repeated tens to hundreds of times. Because of this, for the desired operation of the actuators, it is not easy to obtain the dielectric layers of constant thickness and to keep the area and position of the corresponding electrodes constant. In addition, a complicated process of connecting the electrodes one by one to the stacked corresponding electrodes is required.

In addition, the structure in which many dielectric layers are stacked perpendicularly or the rolled structure in the form of a cylinder of the dielectric layers has a large height and volume, making it difficult to freely apply the dielectric elastomer actuators to skin and curved surfaces.

To further increase the usability of the dielectric elastomer actuators, the operating voltage of the actuators should be low, the actuators should not have a large volume due to the laminated structure, and the manufacturing process of the actuators should be simpler and more economical. Therefore, new dielectric elastomeric actuator structures need to be designed.

### SUMMARY OF THE DISCLOSURE

The present disclosure is to solve the problems and provide an actuator with a multilayered dielectric structure in which a plurality of dielectric layers with short dielectric distances are laterally aligned.

Additionally, the present disclosure is to provide an actuator that can be used by attaching the actuator to various surfaces such as skin and curved surfaces, based on the use of organic materials and a thin and light structure in the form of a thin film.

Additionally, the present disclosure is to provide a method of manufacturing an actuator, the method being economical in terms of time and cost compared to the conventional manufacturing process for dielectric elastomer actuators.

According to one aspect of the present disclosure, an actuator 10 is provided, the actuator including: a polymer frame 100 including a first pattern 110 with a first comb shape of a predetermined thickness and a second pattern 120 with a second comb shape of the predetermined thickness; an electrode 200 including a first electrode 210 formed on a portion of the first pattern 110 and a second electrode 220 formed on a portion of the second pattern 120; and a dielectric elastic portion 300 formed between the first electrode 210 and the second electrode 220 and including a dielectric elastomer.

In addition, a thickness E of the dielectric elastic portion 300 is the same as the predetermined thickness of the polymer frame 100, and the predetermined thickness may be in a range of 2 μm to 100 μm.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

In addition, a ratio D/E of a length D of the first combteeth 111 to a height E of the first electrode and a ratio D/E of a length D of the second combteeth 121 to a height E of the second electrode may be each independently in a range of 10 to 10,000.

A width B of the first combteeth 111 and a width B of the second combteeth 121 may be each independently in a range of 1 μm to 100 μm. The length D of the first combteeth 111 and the length D of the second combteeth 121 may each independently be in a range of 1 mm to 50 mm.

The first electrode 210 may include a first combteeth electrode 211 formed on the walls of the first combteeth 111 and a first support member electrode 212 formed on the upper surface of the first support member 112. The first combteeth electrode 211 and the first support member electrode 212 may be electrically connected to each other. The second electrode 220 may include a second combteeth electrode 221 formed on the walls of the second combteeth 121 and a second support member electrode 222 formed on the upper surface of the second support member 122. The second combteeth electrode 221 and the second support member electrode 222 may be electrically connected to each other.

A distance A between the first combteeth electrode 211 and the second combteeth electrode 221 may be in a range of 1 μm to 100 μm, and a distance C between the first combteeth electrode 211 and the second support member 122 and a distance C between the second combteeth electrode 221 and the first support member 112 may be each independently in a range of 0.025 mm to 25 mm.

The ratio D/C of the length D of the first combteeth 111 to the distance C between the first combteeth electrode 211 and the second support member 122 and the ratio D/C of the length D of the second combteeth 121 to the distance C between the second combteeth electrode 221 and the first support member 112 may independently be in a range of 2 to 40.

The ratio A/E of the distance A between the first combteeth electrode 211 and the second combteeth electrode 221 to the height E of the first electrode 210 and the ratio A/E of the distance A between the first combteeth electrode 211 and the second combteeth electrode 221 to the height E of the second electrode 220 may independently be in a range of 0.01 to 40.

In addition, the dielectric elastic portion 300 may further include at least one selected from the group consisting of ionic liquid and conductive nanoparticles.

Additionally, the dielectric elastic portion 300 may include the dielectric elastomer 310 and may be porous with a plurality of pores 320.

The dielectric elastic portion 300 may further include conductive nanoparticles 330 located on the surface of the pores 320.

An electrostatic force is generated between the first electrode 210 and the second electrode 220 when the electrodes 200 of the actuator 10 are applied with a voltage and the electrostatic force may compress the dielectric elastic portion 300 disposed between the first electrode 210 and the second electrode 220.

According to another aspect of the present disclosure, a method of manufacturing an actuator is provided, the method including: (a) forming a polymer frame 100 including a first pattern 110 with a first comb shape of a predetermined thickness and a second pattern 120 with a second comb shape of the predetermined thickness on a substrate 400; (b) forming a conductive layer 200′ by primary sputtering involving a conductor on the polymer frame 100; (c) forming an electrode 200 including a first electrode 210 formed on a portion of the first pattern 110 and a second electrode 220 formed on a portion of the second pattern 120 by secondary sputtering involving sputtering an inert gas on a portion of the conductive layer 200′; (d) forming a dielectric elastic portion 300 by applying a solution containing a dielectric elastomer and a curing agent between the first electrode 210 and the second electrode 220; and (e) removing the substrate 400 to obtain an actuator 10 including the polymer frame 100, the electrode 200, and the dielectric elastic portion 300.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

The secondary sputtering may be performed in a region except for the conductive layer formed on the upper surface of each of the first support member 112 and the second support member 122. The secondary sputtering may remove the conductive layer laterally formed on the substrate 400 by perpendicularly sputtering the inert gas with respect to the substrate 400.

Young's modulus of the dielectric elastic portion may be controlled according to the content of the curing agent in the solution.

The solution used in the (d) forming of the dielectric elastic portion 300 may further include at least one selected from the group consisting of ionic liquid and conductive nanoparticles.

According to another aspect of the present disclosure, a method of manufacturing an actuator is provided, the method including: (a′) forming a polymer frame 100 including a first pattern 110 with a first comb shape of a predetermined thickness and a second pattern 120 with a second comb shape of the predetermined thickness on a substrate 400; (b′) forming a conductive layer 200′ by sputtering involving a conductor on the polymer frame 100; (c′) forming a dielectric elastic portion 300 located on the conductive layer 200′ and including a dielectric elastomer by applying a solution containing the dielectric elastomer and a curing agent on the conductive layer 200′; and (d′) forming an electrode 200 including a first electrode 210 formed on a portion of the first pattern 110 and a second electrode 220 formed on a portion of the second pattern 120, by removing the substrate 400 and removing the conductive layer on a portion of the upper surface of the polymer frame 100 and the conductive layer on the lower surface of the dielectric elastic portion 300.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

The conductive layer on a portion of the upper surface of the polymer frame 100 and removed in the (d′) forming of the electrode 200 may be a conductive layer located on the upper surface of each of the first combteeth 111 and the second combteeth 121.

The actuators are based on a multilayered dielectric structure in which multiple (>100 layers) dielectric layers with short dielectric distances (<100 μm) are laterally aligned, and can vibrate at an amplitude range of more than 150 μm at an operating voltage of less than 200 V and have an operating force of more than 200 mN.

In addition, the actuators use organic materials and have a thin (<50 μm) and light (<200 mg) structure in the form of a thin film, making it effective in attaching the actuators to various surfaces such as skin and curved surfaces.

The method of manufacturing the actuators is a photolithography process-based manufacturing method, which is more economical in terms of time and cost than the perpendicular lamination manufacturing process of existing dielectric elastomer actuators.

### BRIEF DESCRIPTION OF THE DRAWINGS

Since these drawings are for reference in explaining exemplary embodiments of the present disclosure, the technical idea of the present disclosure should not be interpreted as limited to the attached drawings.

FIG. 1 shows a schematic diagram of an actuator according to an embodiment of the present disclosure;

FIG. 2 shows a schematic diagram illustrating a method of manufacturing an actuator including a secondary sputtering process according to an embodiment of the present disclosure;

FIG. 3 shows a schematic diagram illustrating a method of manufacturing an actuator including the process of etching a conductive layer after etching a sacrificial layer according to an embodiment of the present disclosure;

FIG. 4A shows a schematic diagram illustrating a method of manufacturing an actuator including a porous dielectric elastic portion according to an embodiment of the present disclosure;

FIG. 4B shows a schematic diagram illustrating a method of manufacturing an actuator including a porous dielectric elastic portion with silver (Ag) nanoparticles formed on a pore surface according to an embodiment of the present disclosure;

FIGS. 5A to 5F show images of an actuator observed from above through an optical microscope for each manufacturing part and condition;

FIG. 6 shows images of the overall structure of an actuator manufactured according to Example 1-1 (300 layers), Example 1-2 (600 layers), and Example 1-3 (900 layers), respectively, observed from above;

FIG. 7 shows images of polymer frames and electrodes located on the sides of the frames of Example 1-1, observed with an electron microscope;

FIG. 8 shows images of the cross section of Example 1-10, observed with an electron microscope;

FIGS. 9A to 9C show the appearances of the surface of an actuator and the images of the surface obtained by mapping the components of the applied materials (Au, C) on each surface through electron microscopy and energy component X-ray spectroscopy before gold (Au) sputtering, after gold (Au) sputtering, and after secondary sputtering to clearly show the surface on which the gold (Au) electrode is applied, which changes during the process of manufacturing the actuator according to Example 1;

FIG. 10 shows an actual operation and operating principle of Example 1-3;

FIG. 11 shows a comparison graph of measured values, design theoretical values, and simulation results for the initial capacitance of Examples 1-1, 1-2, 1-3, 1-5, 1-6, 1-9, and 1-10;

FIG. 12 shows a graph illustrating the measured values of initial series resistance and parallel resistance of Examples 1-3, 1-9, and 1-10;

FIG. 13 shows data obtained by measuring the actuation displacement of Examples 1-1, 1-5, and 1-6 and data obtained through COMSOL simulation;

FIG. 14 shows data obtained by measuring the actuation displacement of Examples 1-1 to 1-4 and data obtained through COMSOL simulation;

FIGS. 15A to 15C show simulation design 15A, simulation result 15B, and simulation result graph 15C for comparing the operating forces of an actuator depending on the dielectric distance and number of dielectric layers;

FIGS. 16A to 16C show graphs illustrating mechanical properties 16A, electrical properties 16B of dielectric materials used in Examples 1-3, 1-7, 1-8, 1-9, and 1-10, and static operating distances in Examples 1-3, 1-7, 1-8, 1-9, and 1-10;

FIGS. 17A to 17B show graphs illustrating the dynamic operating distances of Examples 1-3, 1-7, 1-8, 1-9, and 1-10 in absolute value 17A and relative value 17B, respectively;

FIG. 18 shows a graph comparing each of the dielectric distance and number of dielectric layers between the actuators of Examples 1-1 to 1-3, 1-6, and 1-10 and the dielectric elastomer actuator described in various published papers;

FIG. 19 shows a graph illustrating displacement for each operating voltage of Example 1-10 depending on a change in operating frequency; and

FIG. 20 shows graphs measuring the stability of an actuator depending on the operating time and operating repetition experiments of Examples 1-10.

### DESCRIPTION OF THE PREFERRED EMBODIMENTS

Hereinafter, embodiments of the present disclosure will be described in detail with reference to the attached drawings so that those skilled in the art can easily implement the present disclosure.

However, the following description is not intended to limit the present disclosure to specific embodiments, and in describing the present disclosure, if it is determined that a detailed description of related known technology may obscure the gist of the present disclosure, the detailed description will be omitted.

The terminology used herein is only used to describe specific embodiments and is not intended to limit the disclosure. Singular expressions include plural expressions unless the context clearly dictates otherwise. In this application, terms such as “comprise” or “have” are intended to designate the presence of features, numbers, steps, operations, components, or a combination thereof described in the specification. It should be understood that the terms are not intended to preclude the possibility of the existence or addition of the presence of one or more other features or numbers, steps, operations, components, or combinations thereof.

Additionally, terms including ordinal numbers, such as first and second which will be used below, may be used to describe various components, but the components are not limited by the terms. The terms are used only to distinguish one component from another. For example, a first component may be named a second component, and similarly, the second component may also be named a first component without departing from the scope of the present disclosure.

Additionally, when a component is referred to as being “formed” or “laminated” on another component, it may be formed or laminated directly on the entire surface or one side of the surface of the other component, but may also mean that the component is formed or laminated directly on the surface of the other component. In addition, it should be understood that other components may exist.

Hereinafter, a laterally multilayered dielectric elastomer actuator and a method of manufacturing the same will be described in detail. However, this is presented as an example, and the present disclosure is not limited thereby, and the present disclosure is only defined by the scope of the claims to be described later.

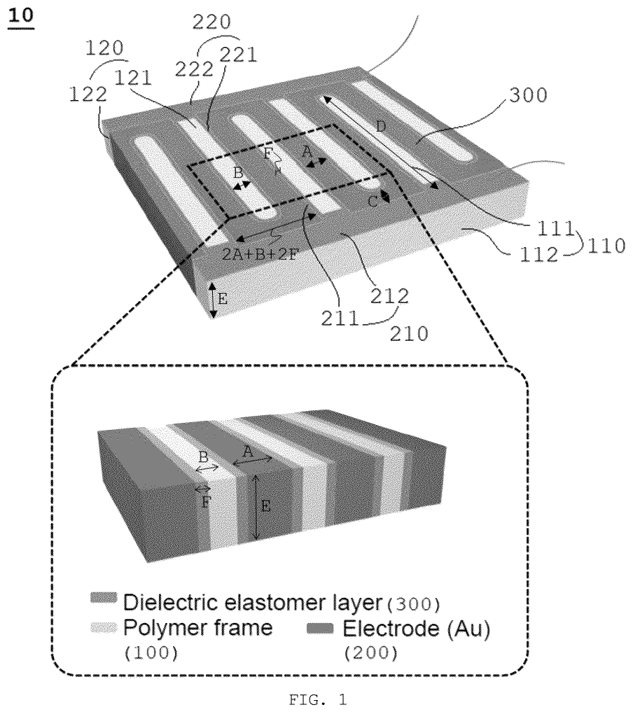

FIG. 1 is a schematic diagram of an actuator according to an embodiment of the present disclosure.

At this time, the part corresponding to the expression E in FIG. 1 is called “height” for an electrode and “thickness” for a polymer frame and a dielectric elastic portion, respectively.

Referring to FIG. 1, the present disclosure provides an actuator 10 which includes: a polymer frame 100 including a first pattern 110 with a first comb shape of a predetermined thickness and a second pattern 120 with a second comb shape of the predetermined thickness; an electrode 200 including a first electrode 210 formed on a portion of the first pattern 110 and a second electrode 220 formed on a portion of the second pattern 120; and a dielectric elastic portion 300 formed between the first electrode 210 and the second electrode 220 and including a dielectric elastomer.

Additionally, the thickness E of the dielectric elastic portion 300 may be equal to the predetermined thickness of the polymer frame 100. When the thickness of the dielectric elastic portion 300 is greater than the thickness of the polymer frame 100, it is undesirable because the mechanical rigidity is large, which interferes with the operation of the actuator. When the thickness E of the dielectric elastic portion 300 is less than that of the polymer frame 100, it is also undesirable because the electrostatic force decreases as there is no dielectric elastic portion between the electrodes of the actuator.

In detail, the predetermined thickness may be in a range of 2 μm to 100 μm. When the thickness is less than 2 μm, it is not desirable because the area of the electrodes located on the sides of each combtooth and facing each other decreases, leading to a reduction in the electrostatic force. In addition, the structural stability of the actuator is reduced due to the thin thickness. When the thickness exceeds 100 μm, it is also undesirable because the flexibility of the thin-filmed actuator decreases.

Even when conventional actuators are made small, the length of each side is several millimeters or more, so it is difficult to expect flexibility of the device within the same number of stacks. However, the actuator of the present disclosure is very thin as one side of the electrode area (thickness E) is limited to 100 μm. Therefore, on the basis of these structural advantages, the actuator of the present disclosure is under research and development as wearable haptic feedback or soft and micro robots.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

In addition, a ratio D/E of a length D of the first combteeth 111 to a height E of the first electrode and a ratio D/E of a length D of the second combteeth 121 to a height E of the second electrode may be each independently in a range of 10 to 10,000. When the ratio D/E is less than 10, it is not desirable because the area where the actuator receives electrostatic force becomes smaller than the overall size of the actuator which leads to a smaller operating force. When the ratio D/E exceeds 10,000, it is not desirable because the area size of the actuator is large and it is difficult to apply the actuator to skin and curved surfaces.

At this time, the height E of the first electrode is a height of a first combteeth electrode 211, and the height E of the second electrode is a height of a second combteeth electrode 221.

Additionally, a width B of the first combteeth 111 and a width B of the second combteeth 121 may each independently be in a range of 1 μm to 100 μm. When the width B is less than 1 μm, it is undesirable because it is difficult to manufacture the actuator using photolithography, and the actuator lacks structural stability. When the width B exceeds 100 μm, mechanical rigidity increases, it is undesirable because it is possible to interfere with the operation of the actuator.

Additionally, the length D of the first combteeth 111 and the length D of the second combteeth 121 may each independently be in a range of 1 mm to 50 mm. When the length D is less than 1 mm, it is undesirable because the area where the actuator receives electrostatic force becomes smaller and the operating force also becomes smaller. When the length D exceeds 50 mm, it is also undesirable because the size of the actuator increases, making it difficult to apply the actuator to skin and curved surfaces.

The first electrode 210 may include the first combteeth electrode 211 formed on the walls of the first combteeth 111 and a first support member electrode 212 formed on the upper surface of the first support member 112. The first combteeth electrode 211 and a first support member electrode 212 may be electrically connected to each other. The second electrode 220 may include the second combteeth electrode 221 formed on the walls of the second combteeth 121 and a second support member electrode 222 formed on the upper surface of the second support member 122. The second combteeth electrode 221 and the second support member electrode 222 may be electrically connected to each other.

At this time, the wall surfaces of the first combteeth and the wall surfaces of the second combteeth mean the side surfaces of the first combteeth and the side surfaces of the second combteeth, respectively.

Additionally, a distance A between the first combteeth electrode 211 and the second combteeth electrode 221 may be in a range of 1 μm to 100 μm. When the distance A is less than 1 μm, it is undesirable because a breakdown phenomenon may occur even at low operating voltage, and when the distance A exceeds 100 μm, the electrostatic force generated when voltage is applied decreases, which reduces the operating distance and force of the actuator.

In addition, a distance C between the first combteeth electrode 211 and the second support member 122 and a distance C between the second combteeth electrode 221 and the first support member 112 may be each independently in a range of 0.025 mm to 25 mm. When the distance C is less than 0.025 mm, it is undesirable because the end portion of the first combteeth electrode facing the second support member (or the end portion of the second combteeth electrode facing the first support member) becomes small, and, in that space, the deformation of the dielectric elastic part is limited, which means a negative impact on the actuator's operating distance and force. When the distance C exceeds 25 mm, it is undesirable because the area on which the actuator receives electrostatic force becomes small relative to the total length of the combteeth, which also means a reduction in the operating force.

The ratio D/C of the length D of the first combteeth 111 to the distance C between the first combteeth electrode 211 and the second support member 122 and the ratio D/C of length D of the second combteeth 121 to the distance C between the second combteeth electrode 221 and the first support member 112 may independently be in a range of 2 to 40. When the ratio D/C is less than 2, it is undesirable because the area where the actuator receives electrostatic force becomes small relative to the total length of the combteeth, which also means a reduction in the operating force. When the ratio D/C exceeds 40, it is also undesirable because the end portion of the first combteeth electrode facing the second support member (or the end portion of the second combteeth electrode facing the first support member) becomes small, and in that space, deformation of the dielectric elastic portion is limited, which means a negative impact on the actuator's operating distance and force.

The ratio A/E of the distance A between the first combteeth electrode 211 and the second combteeth electrode 221 to the height E of the first electrode 210 and the ratio A/E of the distance A between the first combteeth electrode 211 and the second combteeth electrode 221 to the height E of the second electrode 220 may independently be in a range of 0.01 to 40.

In addition, the polymer frame 100 may be at least one selected from the group consisting of epoxy resin, acrylic resin, novolac resin, formaldehyde resin, polymethylmethacrylate, poly(p-xylylene), polyethyleneterephthalate, polybutyleneterephthalate, polyethylenenaphthalate, polystyrene, polycarbonate, polyethylene, polypropylene, polyamide, polyimide, polyurea, polyurethane, polydimethylsiloxane, polystyrenebutadienestyrene, polystyreneethylenebutylenestyrene, polyacrylonitrile butadiene styrene, polydimethylsiloxane (PDMS), polyurea, polyurethane, silicone rubber, fluoro silicone rubber, vinyl methyl silicone rubber, styrene-butadiene-styrene (SBS) block copolymer, styrene-ethylene-butylene-styrene (SEBS) block copolymer, styrene-isoprene-styrene (SIS) block Copolymer, styrene-butadiene rubber (SBR), butadiene rubber (BR), isobutylene isoprene rubber (IIR), ethylene propylene rubber (EPR), ethylene propylene diene monomer rubber (EPDM), isoprene rubber (IR), isobutylene rubber (IR), acrylonitrile butadiene rubber (ABR), polyether urethane, polyester urethane, epichlorohydrin rubber, polychloroprene rubber, acrylic rubber, and ecoflex.

In addition, the first electrode 210 and the second electrode 220 each independently contain at least one selected from the group consisting of gold, titanium, platinum, nickel, palladium, copper, zinc, cadmium, iron, cobalt, iridium, tin, gallium, aluminum, manganese, chromium, molybdenum, tungsten, graphene, carbon nanotubes, graphite, indium tin oxide (ITO), and poly(3,4-ethylenedioxythiophene):poly(styrenesulfonate) (PEPOT:PSS), and may preferably contain gold.

In addition, the dielectric elastomer may contain at least one selected from the group consisting of polydimethylsiloxane (PDMS), polyurea, polyurethane, silicone rubber, fluoro silicone rubber, vinyl methyl silicone rubber, styrene-butadiene-styrene, SBS) block copolymer, styrene-ethylene-butylene-styrene (SEBS) block copolymer, styrene-isoprene-styrene (SIS) block copolymer, styrene-butadiene rubber (SBR), butadiene rubber (BR), isobutylene isoprene rubber (IIR), ethylene propylene rubber (EPR), ethylene propylene diene monomer rubber (EPDM), isoprene rubber (IR), isobutylene rubber (IR), acrylonitrile butadiene rubber (ABR), polyether urethane rubber (polyether urethane), polyester urethane, epichlorohydrin rubber, polychloroprene rubber, acrylic rubber, and ecoflex.

In addition, the dielectric elastic portion 300 may further include at least one selected from the group consisting of ionic liquid and conductive nanoparticles.

Additionally, the ionic liquid may include at least one selected from the group consisting of aliphatic-based ionic liquid, imidazolium-based ionic liquid, and pyridinium-based ionic liquid.

The aliphatic-based ionic liquid is at least one selected from the group consisting of N, N, N-trimethyl-N-propylammonium bis(trifluoromethanesulfonyl)imide (TMPA-TFSI), N-methyl-N-propyl piperidinium bis(trifluoromethanesulfonyl)imide, N, N-diethyl-N-methyl-N-(2-methoxyethyl)ammoniumbis(trifluoromethanesulfonyl)imide, and N, N-diethyl-N-methyl-N-(2-methoxyethyl)ammonium tetrafluoroborate.

The imidazolium-based ionic liquid is at least one selected from the group consisting of 1-ethyl-3-methylimidazolium bis(trifluoromethylsulfonyl)imide, 1-ethyl-3-methylimidazolium bromide, 1-ethyl-3-methyl-imidazolium chloride, 1-ethyl-3-methylimidazolium (L)-lactic acid salt, 1-ethyl-3-methylimidazolium hexafluoro phosphate, 1-ethyl-3-methylimidazolium tetrafluoroborate (EMI-BF4), 1-butyl-3-methylimidazolium chloride, 1-butyl-3-methylimidazolium hexafluorophosphate, 1-butyl-3-methylimidazolium tetrafluoroborate (BMI-BF4), 1-butyl3-methylimidazolium trifluoromethanesulfonate, 1-butyl-3-methylimidazolium (L)-lactic acid salt, 1-hexyl-3-methylimidazolium bromide, 1-hexyl-3-methylimidazolium chloride, 1-hexyl-3-methylimidazolium phosphate, 1-hexyl-3-methylimidazolium hexafluoro tetrafluoroborate, 1-hexyl-3-methylimidazolium trifluoromethane sulfonate, 1-octyl-3-methylimidazolium chloride, 1-Octyl-3-methylimidazolium hexafluoro phosphate, 1-disyl-3-methylimidazolium chloride, 1-dodecyl-3-methylimidazolium chloride, 1-tetradisyl3-methylimidazolium chloride, 1-hexadecyl-3-methylimidazolium chloride, 1-octadecyl-3-methylimidazolium chloride, 1-ethyl-2,3-dimethylimidazolium bromide, 1-ethyl-2,3-dimethyl imidazolium chloride, 1-butyl-2,3-dimethylimidazolium bromide, 1-butyl-2,3-dimethylimidazolium chloride, 1-butyl-2,3-dimethylimidazolium tetrafluoroborate, 1-butyl-2,3-dimethylimidazolium trifluoromethane sulfonate, 1-hexyl-2,3-dimethylimidazolium bromide, 1-hexyl-2,3-dimethylimidazolium chloride, and 1-hexyl-2,3-dimethylimidazolium trifluoromethane sulfonate.

The pyridinium-based ionic liquid is at least one selected from the group consisting of 1-ethyl pyridinium bromide, 1-ethyl pyridinium chloride, 1-butyl pyridinium bromide, 1-butyl pyridinium chloride, 1-butyl pyridinium hexafluoro phosphate, 1-butyl pyridinium tetrafluoroborate, 1-butyl pyridinium trifluoromethane sulfonate, 1-hexyl pyridinium bromide, 1-hexyl pyridinium chloride, 1-hexyl pyridinium hexafluoro phosphate, 1-hexyl pyridinium tetrafluoro borate, and 1-hexyl pyridinium trifluoromethane sulfonate.

The ionic liquid may preferably be an imidazolium-based ionic liquid, and the imidazolium-based ionic liquid may preferably be 1-ethyl-3-methylimidazolium bis(trifluoromethylsulfonyl)imide (EMIM-TFSI).

Additionally, the dielectric elastic portion 300 may include a dielectric elastomer 310 and may be porous with a plurality of pores 320.

The dielectric elastic portion 300 may further include conductive nanoparticles 330 located on the surface of the pores 320.

The conductive nanoparticles 330 may contain at least one selected from the group consisting of gold, silver, platinum, copper, iron, aluminum, titanium, nickel, zinc, magnesium, and carbon.

In addition, an electrostatic force is generated between the first electrode 210 and the second electrode 220 when the electrodes 200 of the actuator 10 are applied with a voltage. This means when voltage is applied, the first electrode 210 and the second electrode 220 have different charges, and an attractive force is generated between the different types of charges, causing compression of the dielectric elastic portion 300 disposed between the first electrode 210 and the second electrode 220.

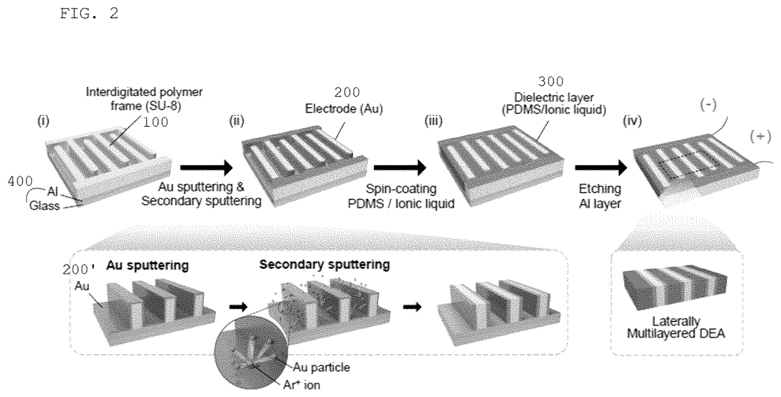

FIG. 2 shows a schematic diagram illustrating a method of manufacturing an actuator including a secondary sputtering process according to an embodiment of the present disclosure.

Referring to FIG. 2, the present disclosure provides a method of manufacturing an actuator, the method including: (a) forming a polymer frame 100 including a first pattern 110 with a first comb shape of a predetermined thickness and a second pattern 120 with a second comb shape of the predetermined thickness on a substrate 400; (b) forming a conductive layer 200′ by primary sputtering involving a conductor on the polymer frame 100; (c) forming an electrode 200 including a first electrode 210 formed on a portion of the first pattern 110 and a second electrode 220 formed on a portion of the second pattern 120 by secondary sputtering involving sputtering an inert gas on a portion of the conductive layer 200′; (d) forming a dielectric elastic portion 300 by applying a solution containing a dielectric elastomer and a curing agent between the first electrode 210 and the second electrode 220; and (e) removing the substrate 400 to obtain an actuator 10 including the polymer frame 100, the electrode 200, and the dielectric elastic portion 300.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

In addition, secondary sputtering may be performed excluding the conductive layer located on the upper surface of each of the first support member 112 and the second support member 122, and secondary sputtering may involve removing the conductive layer formed on the substrate 400 by perpendicularly sputtering the inert gas with respect to the substrate 400.

In detail, the inert gas is ionized and perpendicularly sputtered with the substrate 400, thereby removing the conductive layer laterally formed on the substrate 400.

At this time, the inert gas may include argon.

The conductive particles of the conductive layer laterally formed on the substrate 400 move to the wall surfaces of the first combteeth 111 and the second combteeth 121 through secondary sputtering, respectively, to form a first combteeth electrode 211 located on the walls of the first combteeth 111 and a second combteeth electrode 221 located on the walls of the second combteeth 121.

Young's modulus of the dielectric elastic portion may be controlled according to the content of the curing agent in the solution.

The solution used in the (d) forming of the dielectric elastic portion 300 may further include at least one selected from the group consisting of ionic liquid and conductive nanoparticles.

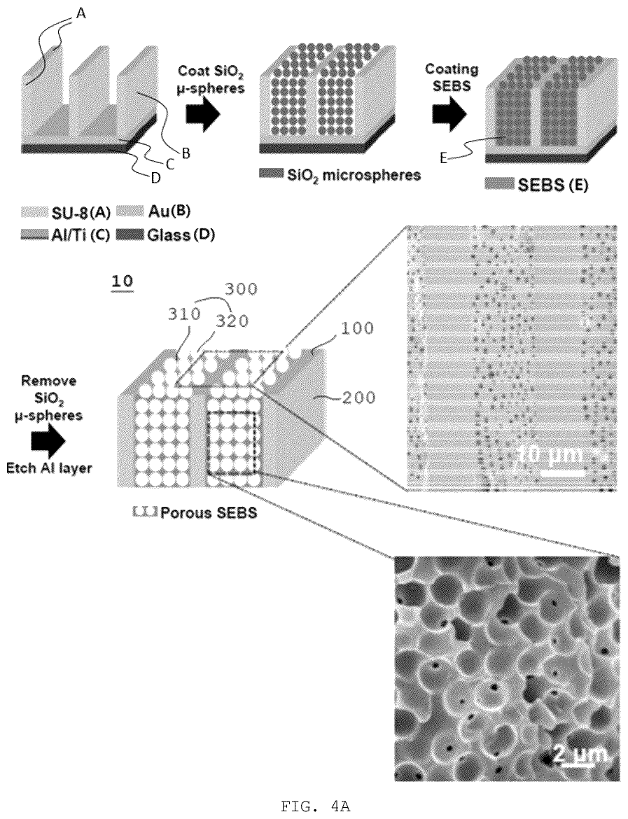

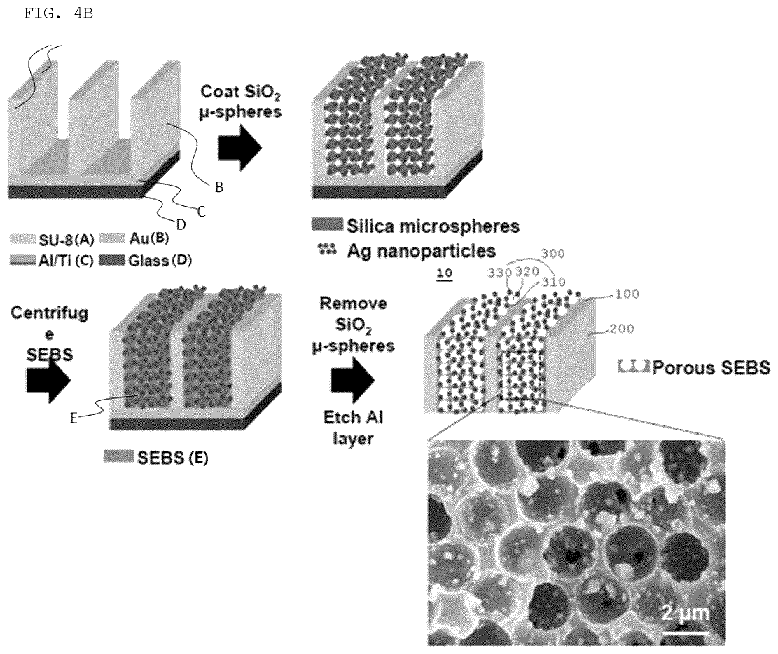

FIG. 4A shows a schematic diagram illustrating a method of manufacturing an actuator including a porous dielectric elastic portion according to an embodiment of the present disclosure, and FIG. 4B shows a schematic diagram illustrating a method of manufacturing an actuator including a porous dielectric elastic portion with silver (Ag) nanoparticles formed on a pore surface according to an embodiment of the present disclosure.

Referring to FIGS. 4A and 4B, the forming of the dielectric elastic portion 300 includes: (d-1) filling a space of an actuator between the first electrode 210 and the second electrode 220 with inorganic microparticles for coating; (d-2) filling the inorganic microparticles-coated space with a dielectric elastomer for coating; and (d-3) removing the inorganic microparticles to form a dielectric elastomer 310 and a porous dielectric elastic portion 300 having a plurality of pores 320.

The inorganic microparticles may include at least one selected from the group consisting of silicon oxide (SiO₂), aluminum oxide (Al₂O₃), titanium oxide (TiO₂), iron oxide (Fe₂O₃ or Fe₃O₄), and zirconium oxide (ZrO₂).

The size of the inorganic microparticles may be in a range of 1 μm to 40 μm. When the size of the inorganic microparticles is less than 1 μm, it is not desirable because it is difficult to fill the space between the inorganic microparticles with the polymer elastomer. When the size of the inorganic microparticles exceeds 40 μm, it is not desirable because the distance A between the first combteeth electrode 211 and the second combteeth electrode 221 is greater than or similar to the height E of each of the first electrode 210 and the second electrode 220, making it difficult to form a stable dielectric layer.

The inorganic micro-particles in the (d-1) filling a space of an actuator between the first electrode 210 and the second electrode 220 with inorganic microparticles for coating may further include metal nanoparticles on the surface, and the dielectric elastic portion 300 may further include the metal nanoparticles 330 located on the surface of the pores 320.

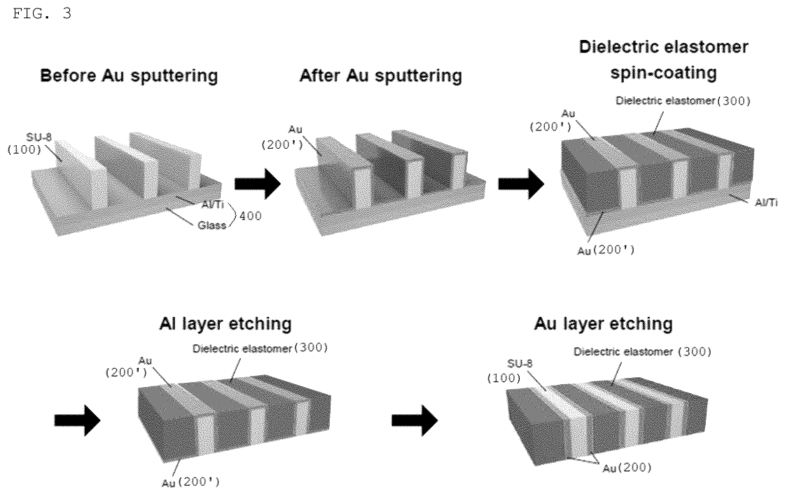

FIG. 3 is a schematic diagram illustrating a method of manufacturing an actuator including the process of etching the conductive layer after etching the sacrificial layer according to an embodiment of the present disclosure.

Referring to FIG. 3, the present disclosure provides a method of manufacturing an actuator, the method including: (a′) forming a polymer frame 100 including a first pattern 110 with a first comb shape of a predetermined thickness and a second pattern 120 with a second comb shape of the predetermined thickness on a substrate 400; (b′) forming a conductive layer 200′ by sputtering involving a conductor on the polymer frame 100; (c′) forming a dielectric elastic portion 300 located on the conductive layer 200′ and including a dielectric elastomer by applying a solution containing a dielectric elastomer and a curing agent on the conductive layer 200′; and (d′) forming an electrode 200 including a first electrode 210 formed on a portion of the first pattern 110 and a second electrode 220 formed on a portion of the second pattern 120 by removing the substrate 400 and removing the conductive layer on a portion of the upper surface of the polymer frame 100 and the conductive layer on the lower surface of the dielectric elastic portion 300.

The first comb shape may include a first combteeth 111 and a first support member 112 supporting the first combteeth 111, the second comb shape may include a second combteeth 121 and a second support member 122 supporting the second combteeth 121, and the first combteeth 111 and the second combteeth 121 may be alternately positioned laterally.

The conductive layer on a portion of the upper surface of the polymer frame 100 and removed in the (d′) forming of the electrode 200 may be a conductive layer formed on the upper surface of each of the first combteeth 111 and the second combteeth 121.

Additionally, the dielectric elastic portion 300 formed in the (c′) forming of the dielectric elastic portion 300 located on the conductive layer 200′ and including a dielectric elastomer by applying a solution containing a dielectric elastomer and a curing agent on the conductive layer 200′ may have the same thickness as the predetermined thickness of polymer frame 100.

### EXAMPLES

Hereinafter, the present disclosure will be described with reference to preferred examples. However, this is for illustrative purposes only and does not limit the scope of the present disclosure.

### Manufacturing of Actuator

### Example 1: Manufacturing Method Including Secondary Sputtering Process (See FIG. 2)

FIG. 1 shows a schematic diagram of an actuator according to an embodiment of the present disclosure. FIG. 2 shows a schematic diagram illustrating a method of manufacturing an actuator including a secondary sputtering process according to an embodiment of the present disclosure. The actuator of Example 1 was manufactured with reference to FIGS. 1 and 2.

First, a polymer frame (SU-8) 100 was manufactured, and the polymer frame included a first pattern 110 with a first comb shape of a predetermined thickness and a second pattern 120 with a second comb shape of the predetermined thickness on a glass substrate 400 on which aluminum (Al) was deposited using a photolithography process. In detail, after depositing Ti/Al (10/100 nm) to serve as a sacrificial layer on the glass substrate, the polymer frame 100 was manufactured using Su-8 which was a negative PR, and the polymer frame was placed on a hot plate and subjected to hardbaking at a temperature of 105° C. for 1 hour. The first comb shape included a first combteeth 111 and a first support member 112 supporting the first combteeth 111, the second comb shape included a second combteeth 121 and a second support member 122 supporting the second comb teeth 121, and the first combteeth 111 and the second combteeth 121 were laterally positioned alternately. The width of each of the manufactured first combteeth 111 and second combteeth 121 was 10 μm. A distance A, hereinafter referred to as the dielectric elastic portion width (dielectric distance) between the first combteeth 111 and the second combteeth 121 was 10 μm, 20 μm, and 40 μm, respectively. The number of combteeth was 150, 300, 600, and 900 for each type. The polymer frame had a thickness in a range of 30 μm to 50 μm depending on the conditions.

Afterward, an electrode 200 was formed in a single process using the secondary sputtering process. The electrode included a first electrode 210 including a first combteeth electrode 211 formed on the walls of the first combteeth 111 and a first support member electrode 212 formed on the upper surface of the first support member 112 and a second electrode 220 including a second combteeth electrode 221 formed on the walls of a second combteeth 121 and a second support member electrode 222 formed on the upper surface of the second support member 122.

At this time, the first combteeth electrode 211 and the first support member electrode 212 were electrically connected to each other, and the second combteeth electrode 221 and the second support member electrode 222 were electrically connected to each other.

In detail, after depositing 50 nm of gold on the entire area of the polymer frame 100 using Au sputter equipment, the gold electrode was left only on the walls of the first combteeth 111 and the second combteeth 121 by removing the gold electrode laterally positioned with the substrate 400 using a secondary sputtering method. Through this, an interdigitated SU-8/Au structure in which multilayered perpendicular electrodes were laterally aligned was manufactured in a single process. At this time, as an exception, the support members 112 and 122 of the polymer frame 100 were covered with a mask before secondary sputtering to prevent the gold electrodes on the upper surfaces of the support members 112 and 122 from being removed by secondary sputtering. As a result, the entire structure had a capacitor-type structure divided into two electrodes centered on the support members 112 and 122 on both sides.

Afterward, the manufactured interdigitated Su-8/Au structure was treated with Oz plasma to make the surface hydrophilic. A composite solution containing an appropriate mixture of PDMS solution and EMIM-TFSI ionic liquid solution was used for spin coating, and then the structure was heat-treated in an oven at a temperature of 60° C. for 4 hours to manufacture a multilayered dielectric elastic portion 300 in a single process. At this time, the weight ratio of the base and curing agent of the polydimethylsiloxane (PDMS) solution used was 10:1, 20:1, and 30:1, respectively. The concentrations of EMIM-TFSI ionic liquid mixed in PDMS were 0% by weight, 5% by weight, and 10% by weight, respectively.

Next, the glass substrate and the actuator were separated by chemically removing the aluminum (Al) layer deposited on the glass substrate using Al etchant. The separated device of the actuator was washed with distilled water and dried.

Finally, to drive the device, both electrodes of the actuator were connected to wires using silver paste.

### Examples 1-1 to 1-9

Actuators of Examples 1-1 to 1-9 were manufactured by varying the combteeth number of the manufactured polymer frame, the distance between the first and second electrodes (width of the dielectric elastic portion, dielectric distance), the ratio of PDMS and curing agent when manufacturing the dielectric elastic portion, and the ionic liquid concentration in the dielectric elastic portion. The results are summarized in Table 1 below.

TABLE 1

| | | Distance | | |
|---|---|---|---|---|
| | | between | | |
| | | the first | | |
| | | and second | Weight | |
| | | electrodes | ratio of | |
| | | (Dielectric | PDMS and | Ionic liquid |
| | Combteeth | distance) | curing | concentration |
| Division | number | (μm) | agent | (wt %) |
| Example 1-1 | 300 | 10 | 30:1 | 0 |
| Example 1-2 | 600 | 10 | 30:1 | 0 |
| Example 1-3 | 900 | 10 | 30:1 | 0 |
| Example 1-4 | 150 | 10 | 30:1 | 0 |
| Example 1-5 | 300 | 20 | 30:1 | 0 |
| Example 1-6 | 300 | 40 | 30:1 | 0 |
| Example 1-7 | 900 | 10 | 10:1 | 0 |
| Example 1-8 | 900 | 10 | 20:1 | 0 |
| Example 1-9 | 900 | 10 | 30:1 | 5 |
| Example 1-10 | 900 | 10 | 30:1 | 10 |

### Example 2: Manufacturing Method Including Etching Conductive Layer after Etching Sacrificial Layer Instead of Secondary Sputtering (See FIG. 3)

FIG. 1 shows a schematic diagram of an actuator according to an embodiment of the present disclosure. FIG. 3 shows a schematic diagram illustrating a method of manufacturing an actuator including the process of etching a conductive layer after etching a sacrificial layer according to an embodiment of the present disclosure. The actuator of Example 2 was manufactured with reference to FIGS. 1 and 3.

In detail, a polymer frame 100 was manufactured in the same manner as in Example 1, and a conductive layer 200′ was manufactured by depositing 50 nm of gold on the entire surface of the polymer frame 100 manufactured using Au sputter equipment. Thereafter, a dielectric elastomer was coated in the same manner as in Example 1 and then hardened by heat treatment to form a dielectric elastic portion 300, and the device manufactured using an Al etchant was separated from a glass substrate.

In the case of the separated device of the actuator, unlike the actuator manufactured in Example 1, the gold conductive layer 200′ was present on the upper surface of the polymer frame 100 and the lower surface of the dielectric elastic portion 300. To separate the electrodes between a combteeth 111 and a combteeth 121 coming from each of a support member 112 and a support member 122, the gold conductive layer present on the upper surface of each of the first and second combteeth 111 and 121 and the lower surface of the dielectric elastic portion 300 was required to be removed. Therefore, the gold conductive layer present on the upper surface of each of the first and second combteeth 111 and 121 and the lower surface of the dielectric elastic portion 300 was removed using an Au etchant, and then a capacitor-type electrode structure divided into two electrodes was created centered on each of the support member 112 and the support member 122 on both sides. At this time, since a multilayered dielectric elastomer existed between the separated electrodes, a laterally aligned multilayered dielectric elastomer actuator could be manufactured.

### Example 3: Manufacturing Method Including Forming Porous Dielectric Elastic Portion

### Example 3-1: Porous Dielectric Elastomer (See FIG. 4A)

FIG. 1 shows a schematic diagram of an actuator according to an embodiment of the present disclosure. FIG. 2 shows a schematic diagram illustrating a method of manufacturing an actuator including a secondary sputtering process according to an embodiment of the present disclosure. FIG. 4A shows a schematic diagram illustrating a method of manufacturing an actuator including a porous dielectric elastic portion according to an embodiment of the present disclosure. The actuator of Example 3-1 was manufactured with reference to FIGS. 1, 2, and 4A.

An interdigitated SU-8/Au structure in which a plurality of electrodes were laterally aligned was manufactured in the same manner as in Example 1.

Afterward, the space of the structure (between the first and second electrodes) was filled with silica microspheres, and then the structure was spin-coated and heat-treated using a liquid dielectric elastomer solution (including SEBS).

Next, an aluminum (Al) layer deposited on the glass substrate of the actuator was chemically removed using an Al etchant, and the silica microspheres were removed using gaseous hydrofluoric acid (HF) to manufacture an actuator containing a dielectric elastic portion with a porous structure.

### Example 3-2: Porous Dielectric Elastic Portion with Silver (Ag) Nanoparticles Formed on Pore Surface (See FIG. 4B)

FIG. 1 shows a schematic diagram of an actuator according to an embodiment of the present disclosure. FIG. 2 shows a schematic diagram illustrating a method of manufacturing an actuator including a secondary sputtering process according to an embodiment of the present disclosure. FIG. 4B shows a schematic diagram illustrating a method of manufacturing an actuator including a porous dielectric elastic portion with silver (Ag) nanoparticles formed on a pore surface according to an embodiment of the present disclosure. The actuator of Example 3-2 was manufactured with reference to FIGS. 1, 2, and 4B.

In detail, the actuator including the porous dielectric elastic portion with silver (Ag) nanoparticles formed on the pore surface was manufactured in the same manner as Example 3-1, except that silica microspheres coated with fine Ag nanoparticles were used instead of silica microspheres.

### EXPERIMENT EXAMPLES

### Experiment Example 1: Confirmation of Actuator Manufacturing

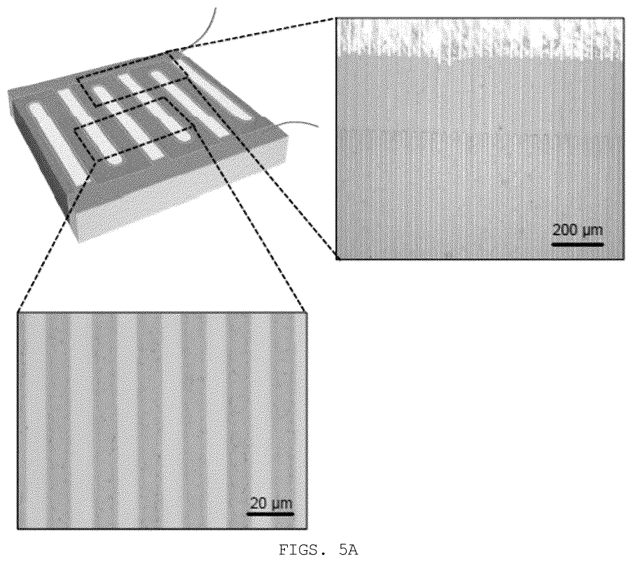

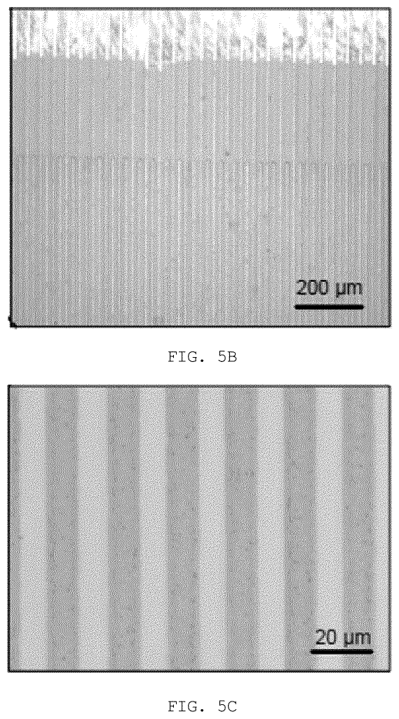

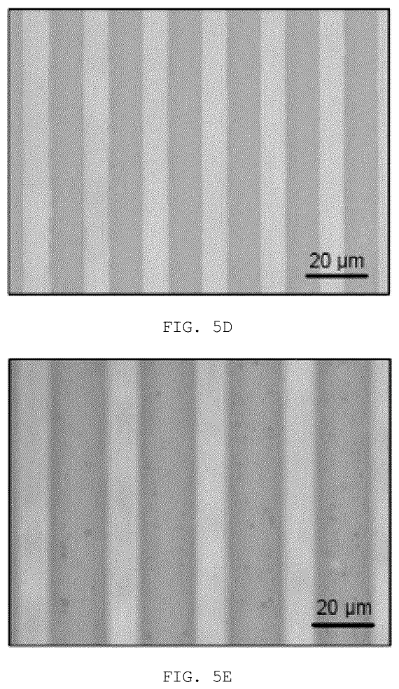

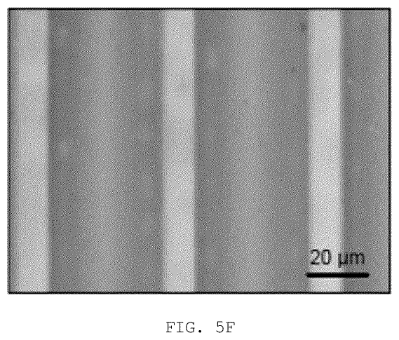

FIGS. 5A to 5F show images of an actuator observed from above through an optical microscope for each manufacturing part and condition.

In detail, FIG. 5A is a schematic diagram of an actuator manufactured according to an embodiment of the present disclosure. FIG. 5B is an image of the starting point of the comb-shaped structure of Example 1-1 observed from above through an optical microscope. FIGS. 5C to 5F are images of the middle portions of Examples 1-1, 1-5, 1-6, and 1-10 observed from above through an optical microscope.

In more detail, FIG. 5C is an image of the middle portion of Examples 1-10 (PDMS+10% by weight of ionic liquid, dielectric distance of 10 μm) observed from above through an optical microscope, FIG. 5D for Example 1-1 (PDMS, dielectric distance of 10 μm), FIG. 5E for Example 1-5 (PDMS, dielectric distance of 20 μm), and FIG. 5F for Example 1-6 (PDMS, dielectric distance of 40 μm).

According to FIG. 5B, the distance C between a first combteeth electrode 211 and a second support member 212 or the distance C between a second combteeth electrode 221 and a first support member 112 was 1 mm.

According to FIGS. 5D to 5F, the widths of each of the first and second combteeth were the same at 10 μm, but the dielectric distance (a distance between a first electrode and second electrode, width of the dielectric elastic portion) was 10 μm and 20 μm, and 40 μm, respectively.

Additionally, according to FIGS. 5C and 5D, an actuator with the same target thickness could be manufactured even by using different types of dielectric elastomers.

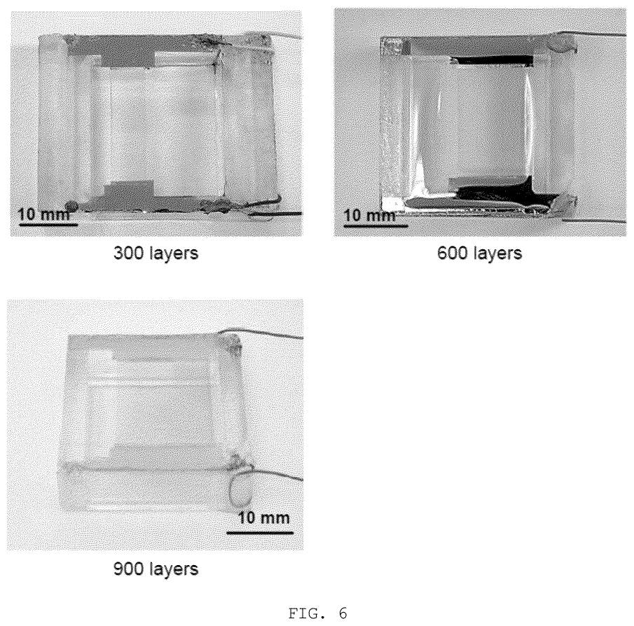

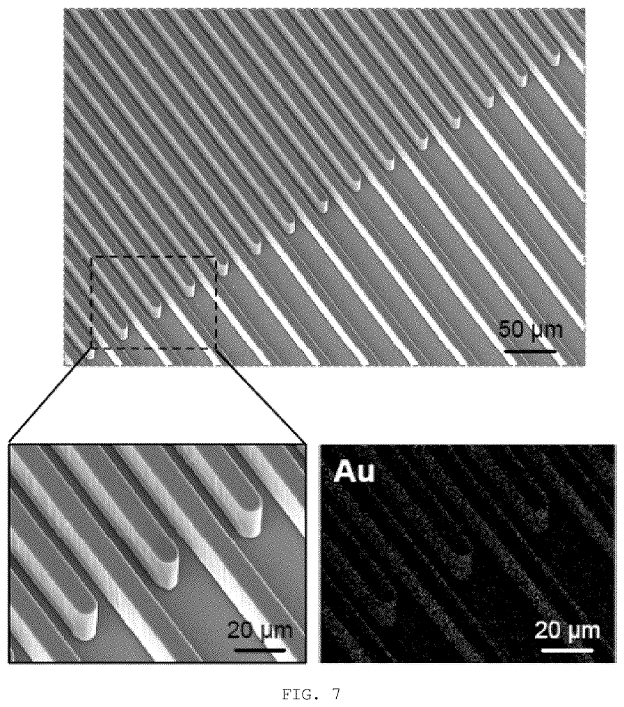

FIG. 6 is images of the overall structure of an actuator manufactured according to Example 1-1 (300 layers), Example 1-2 (600 layers), and Example 1-3 (900 layers), respectively, observed from above.

According to FIG. 6, the total lateral length of the actuator increased as the number of the combteeth in the polymer frame increased to 300, 600, and 900, respectively.

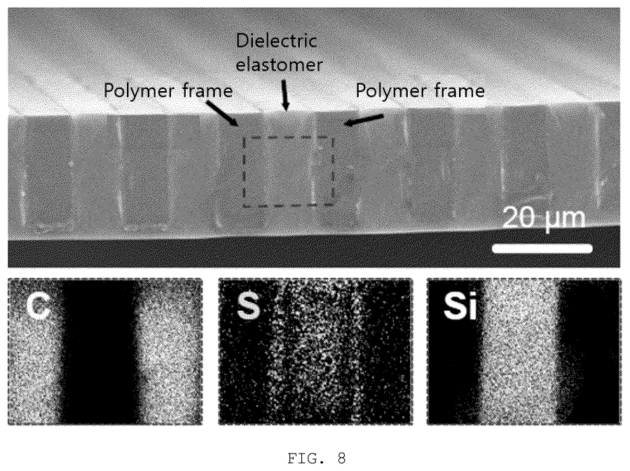

FIG. 7 is images of a polymer frame and electrodes located on the sides of the frame of Example 1-1 observed with an electron microscope.

According to FIG. 7, the combteeth with the thickness E of 35 μm and the length D of 19 mm were aligned laterally at intervals of 10 μm. Additionally, the gold electrode was located on the wall (side) of the comb-tooth structure.

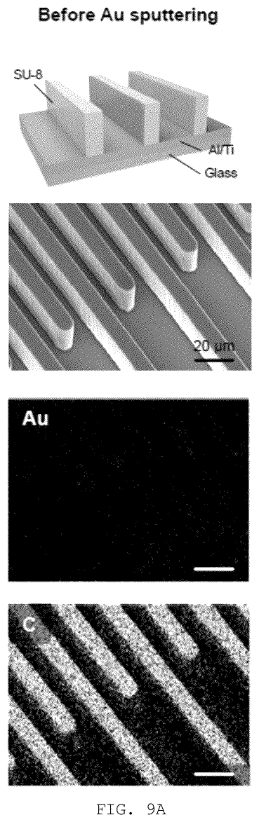

FIG. 8 is images of the cross section of Example 1-10 observed with an electron microscope. In detail, the upper picture of FIG. 8 is a cross-sectional image of Example 1-10 observed with an electron microscope, and the bottom picture of FIG. 8 is an image obtained by mapping the distribution of carbon (C), sulfur (S), and silicon (Si) on the surface using energy component X-ray spectroscopy, as observed with an electron microscope by enlarging the part indicated by the dotted line in the top picture of FIG. 8. In the image, the polymer frame can be distinguished by carbon atoms, the ionic liquid (EMIM-TFSI) by sulfur elements, and the dielectric elastomer (PDMS) by silicon elements.

According to FIG. 8, the ionic liquid was well mixed in the dielectric elastic portion which was already made through the filling of a dielectric elastomer between the polymer frames made of carbon atoms.

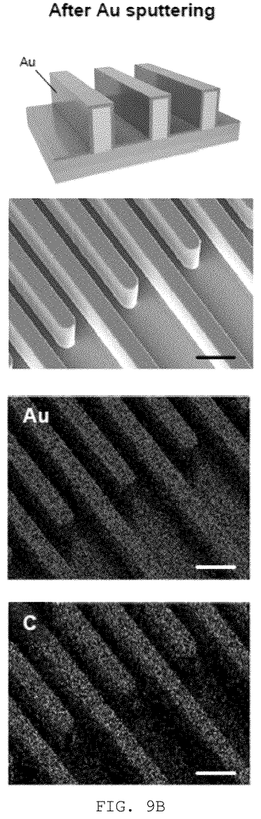

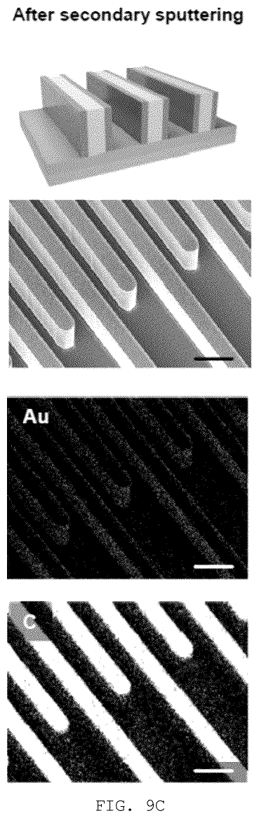

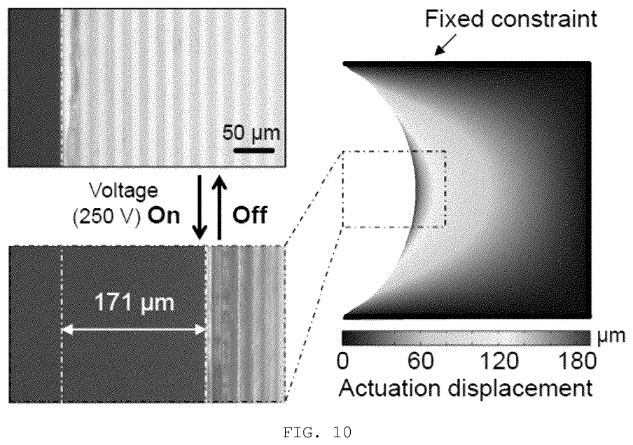

FIGS. 9A to 9C show the appearances of the surface of an actuator and the images of the surface obtained by mapping the components of the applied materials (Au, C) on each surface through electron microscopy and energy component X-ray spectroscopy before gold (Au) sputtering, after gold (Au) sputtering, and after secondary sputtering to clearly show the surface on which the gold (Au) electrode was applied as the gold electrode changes during the process of manufacturing the actuator according to Example 1.

In detail, FIG. 9A is an image of the appearance of the polymer frame manufactured according to Example 1 and the components of the applied materials (Au, C) on each surface obtained through mapping by using electron microscopy and energy component X-ray spectroscopy. FIG. 9B is an image of the distribution of materials (Au, C) on the surface of the structure of the polymer frame 100 obtained through mapping by using energy component X-ray spectroscopy when observing gold deposited on the entire surface of the polymer frame 100 during the manufacturing process of Example 1 with an electron microscope. FIG. 9C is an image of the distribution of gold (Au) on the surface of the structure obtained through mapping by using energy component X-ray spectroscopy when observing gold deposited on the entire surface of the polymer frame 100 after secondary sputtering in the manufacturing process of Example 1 with an electron microscope.

According to FIGS. 9A to 8C, the target actuator was confirmed to be manufactured when manufacturing proceeded by including the secondary sputtering process according to Example 1.

In detail, an electrode 200 was confirmed to be formed including the first electrode 210 formed on a portion of a first pattern 110 and a second electrode 220 formed on a portion of a second pattern 120 by perpendicularly sputtering the inert gas with respect to a substrate 400 and removing the conductive layer laterally formed on the substrate 400.

### Experiment Example 2: Confirmation of Operating Principle of Actuator

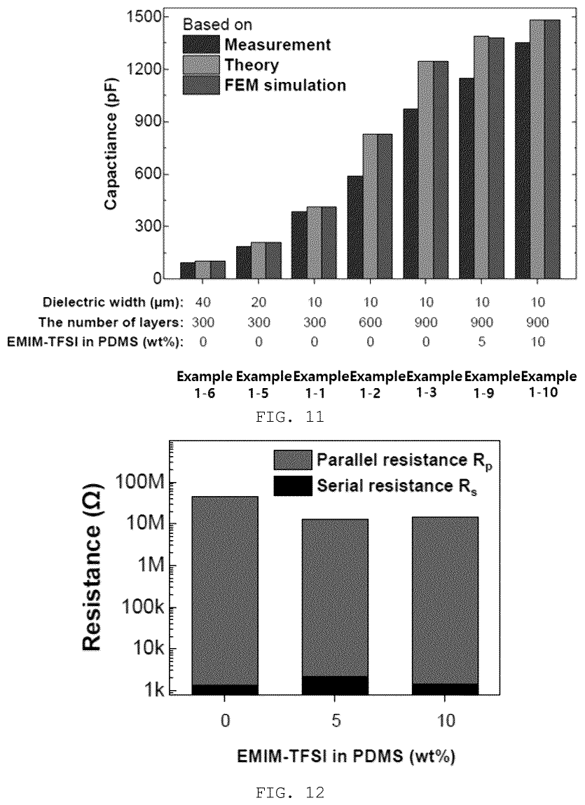

FIG. 10 illustrates an actual operation and operating principle of Example 1-3.

In FIG. 1, when the electrodes 200 were applied with a voltage, an electrostatic force was generated to compress a dielectric elastic portion 300 disposed between the electrodes.

According to FIG. 10, in Examples 1-3, when the surfaces on which first and second support members were located were fixed, one of the two sides parallel to the combteeth of the actuator was fixed, and a voltage of 250 V was applied, the other side (the non-fixed side) of the two sides parallel to the combteeth was confirmed to move due to compression of the dielectric elastic portion. At this time, the moving distance was about 171 μm, which was a measurable distance through observation with an optical microscope.

### Experiment Example 3: Confirmation of Effects Generated by Using Photolithography and Secondary Sputtering in Manufacturing Method

FIG. 11 shows a comparison graph of measured values, design theoretical values, and simulation results for the initial capacitance of Examples 1-1, 1-2, 1-3, 1-5, 1-6, 1-9, and 1-10. FIG. 12 shows a graph illustrating the measured values of initial series resistance and parallel resistance of Examples 1-3, 1-9, and 1-10.

According to FIG. 11, the actual measured capacitance of the actuator was confirmed to be similar to the theoretical value and simulation results even when there are 900 multilayers for the actuator. In other words, the method of manufacturing an actuator used photolithography and secondary sputtering, thereby a multilayered actuator with a short dielectric distance could be manufactured by evenly aligning the bias and ground electrodes perpendicularly so that they faced each other and could be manufactured with a desired design at a microscale.

Also, according to FIG. 12, the actuator was confirmed to have low series resistance due to the high electrical conductivity of the electrodes and to have high parallel resistance because the bias electrode and ground electrode are clearly separated. Due to this stable and predictable impedance, the actuator had a non-uniform dielectric distance but did not experience performance degradation due to the low conductivity of the electrodes.

The method of manufacturing an actuator could form clearly-separated bias and ground electrodes with regular intervals and sizes in a single-cycle process. The method could solve problems such as electrical short circuits and electrode misalignment caused by difficulties in the conventional multilayered actuator manufacturing process and many manufacturing cycles.

Lastly, the actuator had anisotropic transparency due to the laterally aligned electrodes, making it less noticeable when worn on the skin, which has an aesthetically advantageous effect.

### Experiment Example 4: Confirmation of Effects of Thickness of Dielectric Elastic Portion of Actuator (Dielectric Distance, Distance Between Combteeth of Polymer Frame) and Number of Laminated Dielectric Elastic Portion (Number of Polymer Frame Combteeth) on Device Performance

An actuator manufactured according to the present invention operated depending on the operating distance and force equations of conventional dielectric elastomer actuators described below.

$$d = \frac{n {ε}_{0} {ε}_{r} {V}_{OP}^{2}}{E z} \qquad [ Equation 1 ]$$

$$F = \frac{n {ε}_{0} {ε}_{r} {AV}_{OP}^{2}}{{z}^{2}} \qquad [ Equation 2 ]$$

In Equations 1 and 2,
d is an operating distance,
F is an operating force,
n is the number of repeated dielectric layers (number of combteeth in the polymer frame),
ε₀ is the vacuum permittivity,
εᵣ is the relative permittivity of the dielectric elastic portion,
E is Young's modulus of the dielectric elastic portion,
z is the dielectric distance of the dielectric elastic portion (distance between the combteeth of the polymer frame),
A is a corresponding electrode area (=electrode height×electrode length), and
V_{OP} is an operating electrode.

According to the equations, as the number of the dielectric layers (n) of the device increased and the thickness (d) of the dielectric layer became thinner, the strength of the displacement and operating force relative to the operating voltage increased.

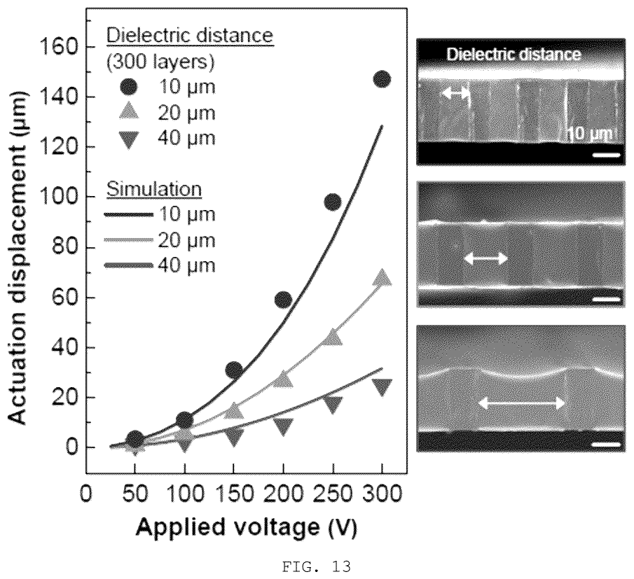

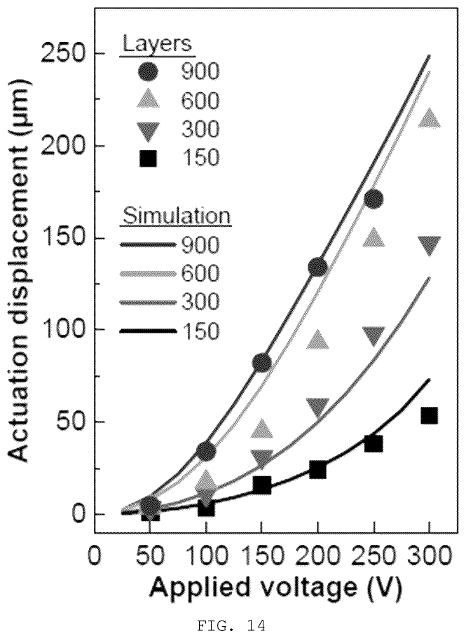

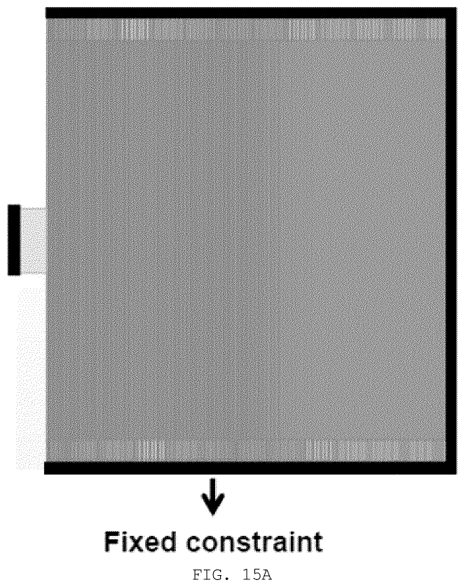

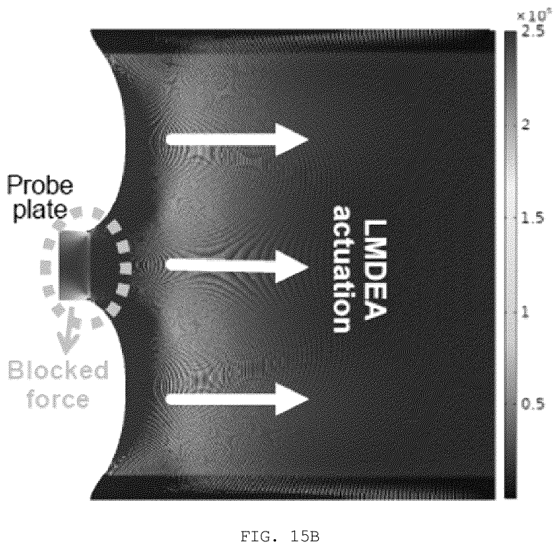

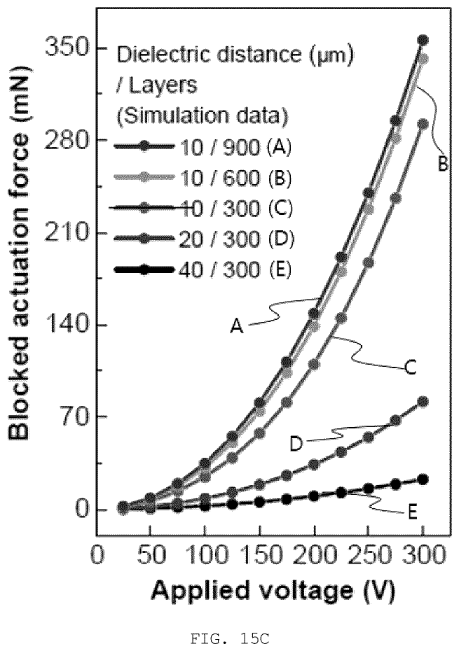

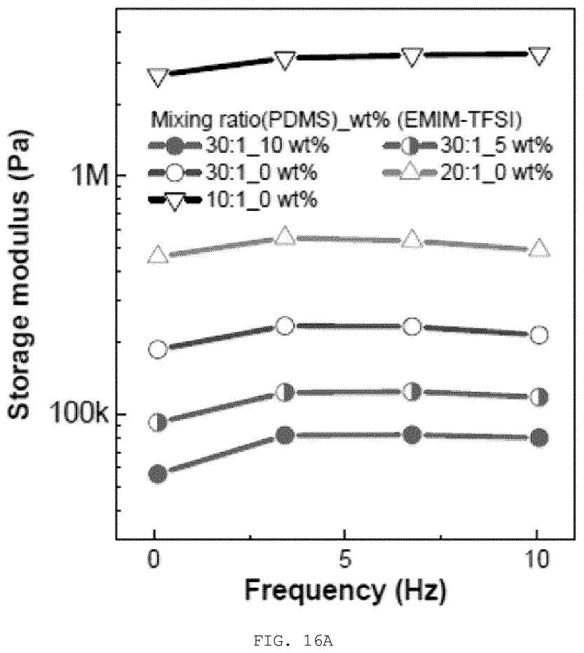

FIG. 13 shows data obtained by measuring the displacement of Examples 1-1, 1-5, and 1-6 and data obtained through COMSOL simulation. FIG. 14 shows data obtained by measuring the displacement of Examples 1-1 to 1-4 and data obtained through COMSOL simulation. FIGS. 15A to 15C show simulation design 15A, simulation result 15B, and simulation result graph 15C for comparing the operating forces of an actuator of the present disclosure depending on the dielectric distance and number of dielectric layers.

According to FIGS. 13 and 15, at the same number of dielectric elastic layers (number of polymer frame combteeth) (300 layers), Example 1-1 (10 μm) with a thinner thickness of the dielectric elastic portion (dielectric distance, distance between polymer frame combteeth) than Examples 1-5 (20 μm) and 1-6 (40 μm) was confirmed to have an increased actuation displacement relative to operating voltage.

According to FIGS. 14 and 15, at the same thickness of the dielectric elastic portion (dielectric distance, distance between polymer frame combteeth) (10 μm), the actuation displacement was confirmed to increase relative to the operating voltage as the number of the laminated dielectric elastic portion (the number of polymer frame comb teeth) increased.

### Experiment Example 5: Confirmation of Effects of Mechanical and Electrical Properties of Dielectric Materials on Device Displacement

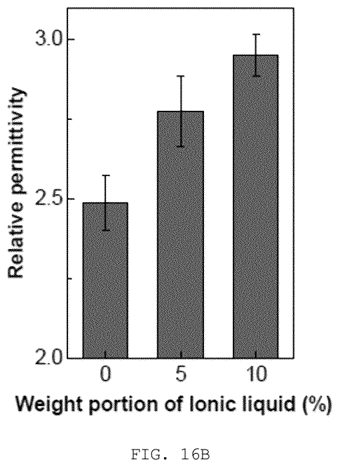

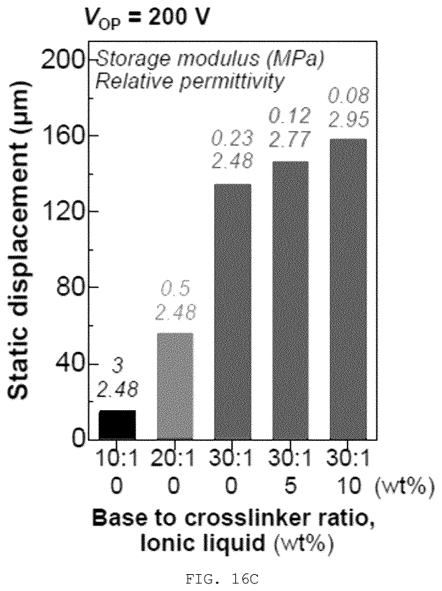

FIGS. 16A to 16C are graphs illustrating mechanical properties 16A, electrical properties 16B of dielectric materials used in Examples 1-3, 1-7, 1-8, 1-9, and 1-10, and static operating distances in Examples 1-3, 1-7, 1-8, 1-9, and 1-10.

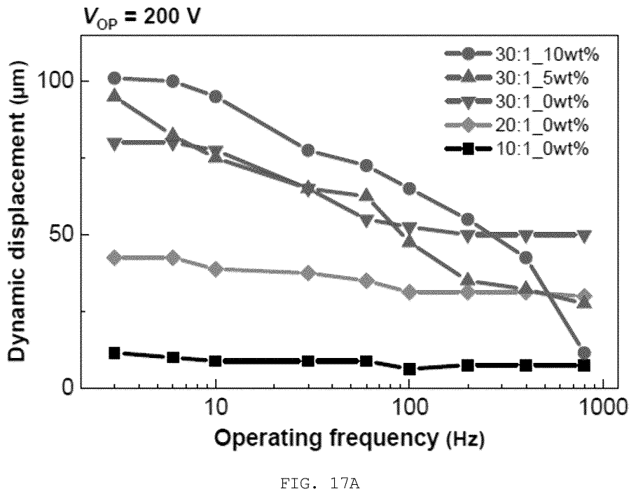

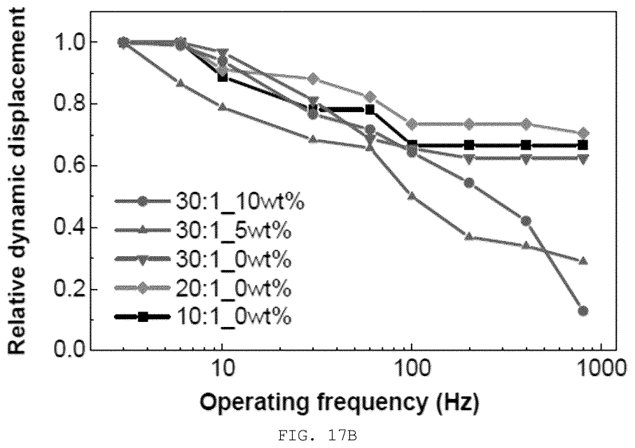

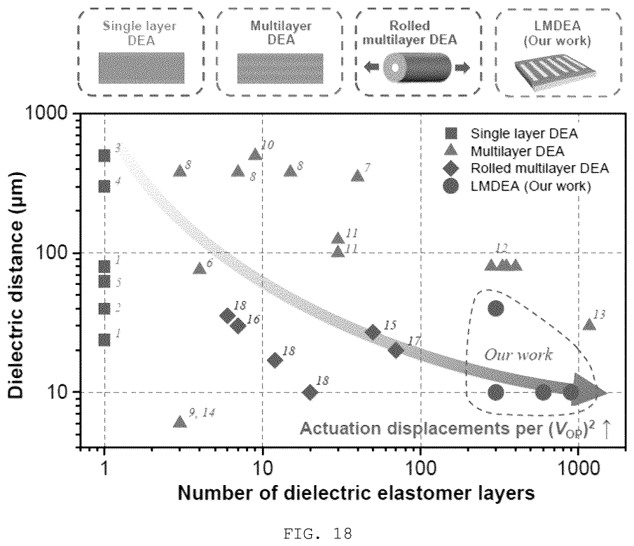

FIGS. 17A to 17B are graphs illustrating the dynamic operating distances of Examples 1-3, 1-7, 1-8, 1-9, and 1-10 in absolute value 17A and relative value 17B, respectively.

According to the equation described in Experiment Example 3, as Young's modulus E of the dielectric layer decreased and the relative permittivity (εᵣ) increased, the strength of the displacement and operating force relative to the operating voltage increased. Therefore, the relative permittivity (εᵣ) of the dielectric layer was increased while Young's modulus was further lowered by adjusting the base-to-crosslinker ratio to 10:1, 20:1, and 30:1 (Examples 1-7, 1-8, 1-3), respectively, so that Young's modulus of the dielectric layer was lowered, and at the same time by adding 5% by weight and 10% by weight of ferroelectric ionic liquid (EMIM-TFSI) to PDMS (Examples 1-9 and 1-10), respectively, and mixing the solutions of the ionic liquid and PDMS.

In detail, according to FIGS. 16A to 16C, the smaller the storage modulus, and the larger the relative permittivity, the larger the displacement relative to the operating voltage.

In addition, according to FIGS. 17A and 17B, the weight ratio of PDMS and curing agent was 30:1 in the frequency range of 0 Hz to 200 Hz, which was the frequency range in which sensation could be mainly detected on the skin, and the displacement was highest when the dielectric elastic portion with 10% by weight of ionic liquid added (Example 1-10) was used.

### Experiment Example 6: Confirmation of the Driving Performance of the Optimized Device of Actuator

According to Experiment Examples 4 and 5, the optimized conditions (Examples 1-10) of the actuator were confirmed.

FIG. 18 is a graph comparing each of the dielectric distance and number of dielectric layers between the actuators of Examples 1-1 to 1-3, 1-6, and 1-10 and the dielectric elastomer actuator described in papers. The papers described in FIG. 18 are summarized in Table 2 below.

TABLE 2

| | | | Operating |
|---|---|---|---|
| | | | distance |
| Numbers | | | efficiency |
| shown in | Actuator | | (×10⁶) |
| FIG. 18 | type | Papers | [μm/V²] |
| Our work | Lateral | Example 1-3 of the | 4,000 |
| | Multilayer | present disclosure | |
| 1 | Single layer | Science 287, 686 | 0.5 |
| | | (2000) | |
| 2 | Single layer | Adv. Mater. 18, 887 | 0.2 |
| | | (2006) | |
| 3 | Single layer | J. Mater. Chem. C 5, | 0.5 |
| | | 6834 (2017) | |
| 4 | Single layer | Compos. Sci. Technol. | 1.75 |
| | | 156, 151 (2018) | |
| 5 | Single layer | Nat. Commun. 12, 4517 | 1.75 |
| | | (2021) | |
| 6 | Multilayer | Sens. Actuator A Phys. | 0.75 |
| | | 167, 459 (2011) | |
| 7 | Multilayer | Smart Mater. Struct. | 69.5 |
| | | 27, 075023 (2018) | |
| 8 | Multilayer | Adv. Funct. Mater. | 5.25 |
| | | 30, 1907375 (2020) | |
| 9 | Multilayer | Adv. Funct. Mater. | 6 |
| | | 31, 2006639 (2021) | |
| 10 | Multilayer | Front. Robot. AI 8, | 1 |
| | | 714332 (2021) | |
| 11 | Multilayer | Chem. Eng. J. 364, | 2.25 |
| | | 217 (2019) | |
| 12 | Multilayer | Sens. Actuator A | 860 |
| | | Phys. 155, 299 (2009) | |
| 13 | Multilayer | PNAS 116, 2476 (2019) | 600 |
| 14 | Multilayer | Sci. Robot. 4, | 6.5 |
| | | eaaz6451 (2019) | |
| 15 | Rolled | Adv. Funct. Mater. | 800 |
| | Multilayer | 28, 1804328 (2018) | |
| 16 | Rolled | Nature 575, 324 | 710 |
| | Multilayer | (2019) | |
| 17 | Rolled | Soft Robotics 7, | 1,000 |
| | Multilayer | 451 (2020) | |
| 18 | Rolled | Adv. Mater. 34, | 2,897.5 |
| | Multilayer | 2106757 (2022) | |

According to FIG. 18, the actuator had significantly superior conditions to other dielectric elastomer actuators presented in existing papers. In detail, the operating distance (d/V_{OP}²) compared to the square of the applied voltage derived from Equation 1 was defined as operating distance efficiency, and the actuator of the present invention was compared with the other dielectric elastomer actuators. As a result, the actuator of the present invention showed the highest operating distance efficiency.

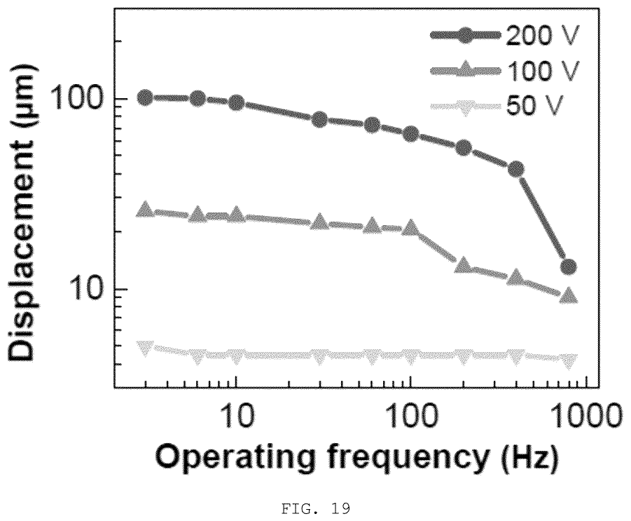

FIG. 19 is a graph illustrating displacement for each operating voltage of Example 1-10 depending on a change in operating frequency.

According to FIG. 19, the change in displacement depending on the change in operating voltage follows Equations 1 and 2 described in Experiment Example 4. Therefore, the actuator of the present invention can control the displacement by adjusting the operating voltage.

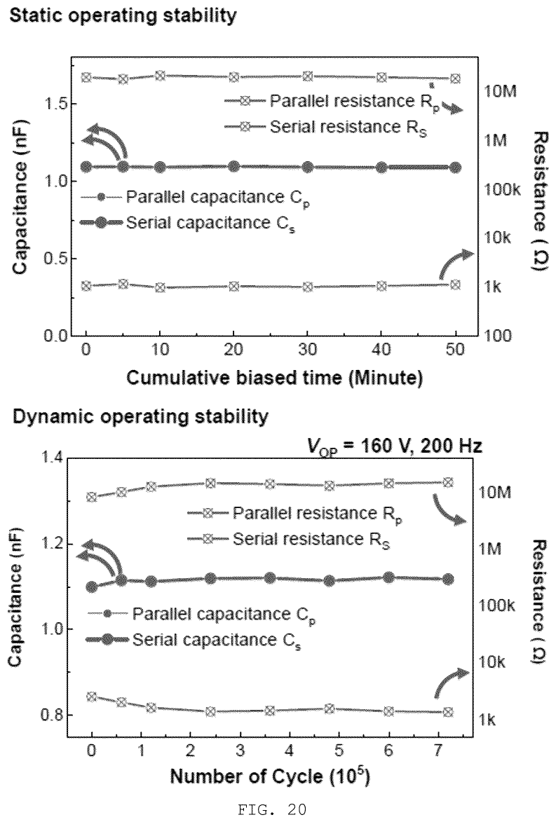

FIG. 20 is graphs measuring the stability of an actuator depending on the operating time and operating repetition experiments of Examples 1-10.

In detail, the upper graph of FIG. 20 is a graph showing the series capacitor (C_{S}), parallel capacitor (C_{P}), series resistance (R_{S}), and parallel resistance (R_{P}) depending on the number of operating cycles in Examples 1-10 when the operating voltage is 160 V and the operating frequency is 0 Hz.

The stability of the device of the actuator was confirmed through the three indicators below.

The capacitor values of the bias electrode and ground electrode represented the capacitance of the actuator. For the actuator to have a sufficient electrostatic force, the capacitor value was required to be large. (1) Since there should be no connection between the bias electrode and the ground electrode, the parallel resistance (R_{P}) value of the capacitor, which represented the resistance between the two electrodes, was required to be high.
(2) For each electrode constituting the bias electrode and the ground electrode to function as an electrode, the series resistance (R_{S}) value of the capacitor was required to be small.
(3) When there was no connection between the bias electrode and the ground electrode, and each electrode properly performed its role as an electrode, the capacitor value (C_{P}) measured considering parallel resistance and the capacitor value (C_{S}) measured considering series resistance were required to be at the same level, and must be at the same level as the theoretical value as shown in FIG. 11.

Based on this, the device of the actuator manufactured according to the present invention operated stably even when voltage continued to be applied for more than one hour.

The bottom graph of FIG. 20 is a graph showing C_{P}, C_{S}, R_{P}, and R_{S} depending on the number of operating cycles of the device when the operating voltage is 160 V and the operating frequency is 200 Hz.

Based on this, the device of the actuator manufactured stably operated for more than 7000 k times.

The scope of the present disclosure is indicated by the claims described below rather than the detailed description above, and all changes or modified forms derived from the meaning and scope of the claims and their equivalent concepts should be construed as being included in the scope of the present disclosure.

What is claimed is:

1. An actuator comprising:
a polymer frame comprising a first pattern with a first comb shape of a predetermined thickness and a second pattern with a second comb shape of the predetermined thickness;
an electrode comprising a first electrode formed on a portion of the first pattern and a second electrode formed on a portion of the second pattern; and
a dielectric elastic portion formed between the first electrode and the second electrode and comprising a dielectric elastomer.

2. The actuator of claim 1, wherein the dielectric elastic portion has a thickness equal to the predetermined thickness of the polymer frame, and
the predetermined thickness is in a range of 2 μm to 100 μm.

3. The actuator of claim 1, wherein the first comb shape comprises a first combteeth and a first support member supporting the first combteeth,
the second comb shape comprises a second combteeth and a second support member supporting the second combteeth, and
the first combteeth and the second combteeth are laterally positioned alternately.

4. The actuator of claim 3, wherein a ratio of a length of the first combteeth to a height of the first electrode and a ratio of a length of the second combteeth to a height of the second electrode are each independently in a range of 10 to 10,000.

5. The actuator of claim 3, wherein a width of the first combteeth and a width of the second combteeth are each independently in a range of 1 μm to 100 μm, and
the length of the first combteeth and the length of the second combteeth are each independently in a range of 1 mm to 50 mm.

6. The actuator of claim 3, wherein the first electrode comprises a first combteeth electrode formed on walls of the first combteeth and a first support member electrode formed on the upper surface of the first support member,
the first combteeth electrode and the first support member electrode are electrically connected to each other,
the second electrode comprises a second combteeth electrode formed on walls of the second combteeth and a second support member electrode formed on the upper surface of the second support member, and
the second combteeth electrode and the second support member electrode are electrically connected to each other.

7. The actuator of claim 6, wherein a distance between the first combteeth electrode and the second combteeth electrode is in a range of 1 μm to 100 μm, and
a distance between the first combteeth electrode and the second support member and a distance between the second combteeth electrode and the first support member are each independently in a range of 0.025 mm to 25 mm.

8. The actuator of claim 6, wherein a ratio of the length of the first combteeth to a distance between the first combteeth electrode and the second support member and a ratio of the length of the second combteeth to a distance between the second combteeth electrode and the first support member are each independently in a range of 2 to 40.

9. The actuator of claim 6, wherein a ratio of a distance between the first combteeth electrode and the second combteeth electrode to a height of the first electrode and a ratio of a distance between the first combteeth electrode and the second combteeth electrode to a height of the second electrode are each independently in a range of 0.01 to 40.

10. The actuator of claim 1, wherein the dielectric elastic portion further comprises at least one selected from the group consisting of ionic liquid and conductive nanoparticles.

11. The actuator of claim 1, wherein the dielectric elastic portion comprises the dielectric elastomer and is porous with a plurality of pores.

12. The actuator of claim 11, wherein the dielectric elastic portion further comprises conductive nanoparticles located on the surface of the pores.

13. The actuator of claim 1, wherein an electrostatic force is generated between the first electrode and the second electrode when the electrodes of the actuator are applied with a voltage, and the electrostatic force compresses the dielectric elastic portion disposed between the first electrode and the second electrode.

14. A method of manufacturing an actuator, the method comprising:
(a) forming a polymer frame comprising a first pattern with a first comb shape of a predetermined thickness and a second pattern with a second comb shape of the predetermined thickness on a substrate;
(b) forming a conductive layer by primary sputtering involving sputtering a conductor on the polymer frame;
(c) forming an electrode comprising a first electrode formed on a portion of the first pattern and a second electrode formed on a portion of the second pattern by secondary sputtering involving sputtering an inert gas on a portion of the conductive layer;
(d) forming a dielectric elastic portion by applying a solution containing a dielectric elastomer and a curing agent between the first electrode and the second electrode; and
(e) removing the substrate to obtain an actuator comprising the polymer frame, electrode, and dielectric elastic portion.

15. The method of claim 14, wherein the first comb shape comprises a first combteeth and a first support member supporting the first combteeth,
the second comb shape comprises a second combteeth and a second support member supporting the second combteeth, and
the first combteeth and the second combteeth are laterally positioned alternately.

16. The method of claim 15, wherein the secondary sputtering is performed in a region except for the conductive layer formed on the upper surface of each of the first support member and the second support member, and
the secondary sputtering involves perpendicularly sputtering the inert gas with respect to the substrate, thereby removing the conductive layer laterally formed on the substrate.

17. The method of claim 14, wherein Young's modulus of the dielectric elastic portion is controlled according to the content of the curing agent in the solution.

18. The method of claim 14, wherein the solution used in the (d) forming of the dielectric elastic portion further comprises at least one selected from the group consisting of ionic liquid and conductive nanoparticles.

19. A method of manufacturing an actuator, the method comprising:
(a′) forming a polymer frame comprising a first pattern with a first comb shape of a predetermined thickness and a second pattern with a second comb shape of the predetermined thickness on a substrate;
(b′) forming a conductive layer by sputtering a conductor on the polymer frame;
(c′) forming a dielectric elastic portion on the conductive layer, the dielectric elastic portion comprising a dielectric elastomer, by coating the conductive layer with a solution containing the dielectric elastomer and a curing agent; and
(d′) forming an electrode comprising a first electrode formed on a portion of the first pattern and a second electrode formed on a portion of the second pattern by removing the substrate and removing the conductive layer formed on a portion of an upper surface of the polymer frame and the conductive layer on a lower surface of the dielectric elastic portion.

20. The method of claim 19, wherein the first comb shape comprises a first combteeth and a first support member supporting the first combteeth,
the second comb shape comprises a second combteeth and a second support member supporting the second combteeth, and
the first combteeth and the second combteeth are laterally positioned alternately.

21. The method of claim 20, wherein the conductive layer on the portion of the upper surface of the polymer frame and then removed in the (d′) forming of an electrode is the conductive layer positioned on an upper surface of each of the first combteeth and the second combteeth.
